(19) United States
(12) Patent Application Publication
(10) Pub. No.: US 2024/0114701 A1
(43) Pub. Date: Apr. 4, 2024

(54) NONVOLATILE MEMORY DEVICE AND MANUFACTURING METHOD THEREOF

(71) Applicant: SONY SEMICONDUCTOR SOLUTIONS CORPORATION, KANAGAWA (JP)

(72) Inventors: JUN SUMINO, KANAGAWA (JP); KATSUHISA ARATANI, KANAGAWA (JP); TAKEYUKI SONE, KANAGAWA (JP); TETSUYA MIZUGUCHI, KANAGAWA (JP)

(21) Appl. No.: 18/261,655

(22) PCT Filed: Dec. 7, 2021
(86) PCT No.: PCT/JP2021/044814

§ 371 Date: Jul. 14, 2023

(30) Foreign Application Priority Data
Jan. 22, 2021 (JP) 2021-009054

(51) Int. Cl. H10B 63/00; H10N 70/00

(52) U.S. Cl. CPC H10B 63/20; H10B 63/80; H10N 70/063; H10N 70/826; H10N 70/881

(57) ABSTRACT

Provided is a nonvolatile memory device that makes it possible to achieve high performance. The nonvolatile memory device includes a first electrode, a memory material layer, a second electrode, and a first buffer layer. The memory material layer includes a first element and is provided on the first electrode. The second electrode is provided on the memory material layer. The first buffer layer is provided between the memory material layer and the second electrode. In the first buffer layer, a segregation of the first element is smaller than a segregation of the first element in the second electrode.

### TECHNICAL FIELD

The present disclosure relates to a nonvolatile memory device and a manufacturing method thereof.

### BACKGROUND ART

Patent Literature 1 discloses a ferroelectric memory and a method of manufacturing the same. In this ferroelectric memory, a capacitor is formed by sequentially laminating a perovskite-type conductive oxide film, a ferroelectric film, and a perovskite-type conductive oxide film between a lower electrode and an upper electrode. The capacitor is configured as a memory unit that stores information of a memory cell.

### CITATION LIST

### Patent Literature

Patent Literature 1: Japanese Unexamined Patent Application Publication No. 2008-270596

### SUMMARY OF THE INVENTION

A ferroelectric memory is a nonvolatile memory device included in a storage class memory (SCM: Storage Class Memory) category. In this type of nonvolatile memory device, attempts have been made to achieve high performance by constructing a memory unit of a memory cell by employing a new memory material while effectively utilizing an existing manufacturing process. In order to achieve high performance, it is necessary to reduce a fluctuation in electrical characteristics of the memory unit and variations in the electrical characteristics.

The present disclosure provides a non-volatile memory device that makes it possible to achieve high performance and a method of manufacturing the same.

A nonvolatile memory device according to a first embodiment of the present disclosure includes: a first electrode; a memory material layer provided on the first electrode and including a first element; a second electrode provided on the memory material layer; and a first buffer layer provided between the memory material layer and the second electrode, the first buffer layer having a segregation of the first element smaller than a segregation of the first element in the second electrode.

A method of manufacturing a nonvolatile memory device according to a second embodiment of the present disclosure includes: forming a first electrode on a substrate; forming a memory material layer including a first element on the first electrode; forming a first buffer layer on the memory material layer; forming, on the first buffer layer, a second electrode layer having a segregation of the first element larger than a segregation of the first element in the first buffer layer; forming a second electrode by patterning the second electrode layer by a first etching process that uses the first buffer layer as a stopper; and patterning the first buffer layer and the memory material layer by a second etching process that is different from the first etching process.

### BRIEF DESCRIPTION OF THE DRAWINGS

FIG. 1 is a schematic cross-sectional view including a main part of a memory cell array region of a nonvolatile memory device according to a first embodiment of the present disclosure.

FIG. 2 is an enlarged cross-sectional view of a memory cell in the memory cell array region illustrated in FIG. 1.

FIG. 3 is a diagram illustrating an amount of composition element of a memory material layer in a region from a memory material layer to a second electrode of the memory cell illustrated in FIG. 2.

FIG. 4 is a cross-sectional view of a first step corresponding to FIG. 2 for explaining a manufacturing method of the nonvolatile memory device according to the first embodiment of the present disclosure.

FIG. 5 is a cross-sectional view of a second step for explaining the manufacturing method of the nonvolatile memory device.

FIG. 6 is a cross-sectional view of a third step for explaining the manufacturing method of the nonvolatile memory device.

FIG. 7 is a cross-sectional view of a fourth step for explaining the manufacturing method of the nonvolatile memory device.

FIG. 8 is an enlarged cross-sectional view corresponding to FIG. 2 of a nonvolatile memory device according to a second embodiment of the present disclosure.

### MODES FOR CARRYING OUT THE INVENTION

Hereinafter, some embodiments of the present disclosure are described in detail with reference to the drawings. The description will be made in the following order.

### 1. First Embodiment

In a first embodiment, an example will be described in which the present technology is applied to a cross-point memory constructed by a resistance change memory cell as a nonvolatile memory device.

### 2. Second Embodiment

In a second embodiment, an example will be described in which a structure of the resistance change memory cell is changed in the nonvolatile memory device according to the first embodiment.

### First Embodiment

### [Configuration of Nonvolatile Memory Device 1]

### (1) Schematic Configuration of Nonvolatile Memory Device 1

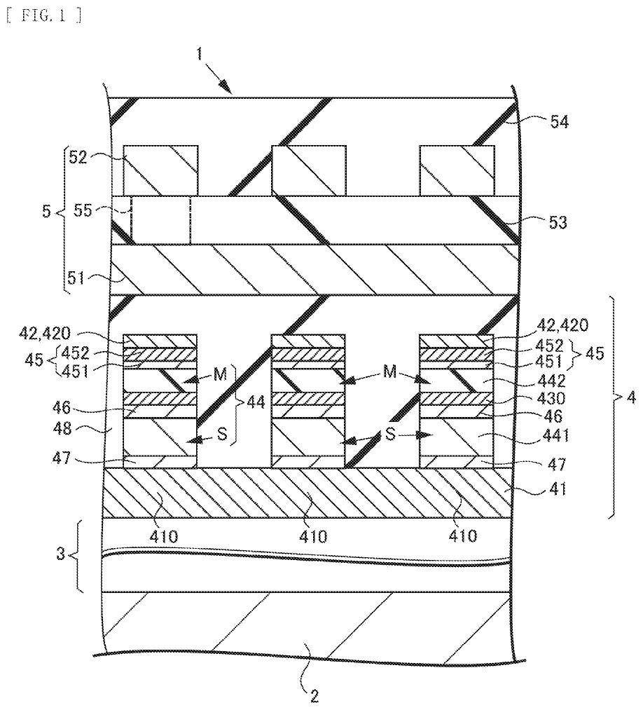

FIG. 1 illustrates a schematic cross-sectional configuration example of a nonvolatile memory device 1 according to a first embodiment of the present disclosure.

As illustrated in FIG. 1, the nonvolatile memory device 1 has, for example, a structure in which a substrate 2, a transistor region 3, a memory cell array region 4, and a wiring region 5 are stacked in this order. When viewed from a direction perpendicular to the main surface of the substrate 2 (hereinafter, simply referred to as “plan view”), a plurality of resistance change memory cells are arranged in a matrix in the memory cell array region 4. The nonvolatile memory device 1 is a cross-point type resistance change memory (ReRAM: Resistive Random Access Memory). A structure and a manufacturing method of the resistance change memory cell will be described later.

Here, the main surface of the substrate 2 is a main surface of the substrate 2 in which a semiconductor device such as a transistor is manufactured in the transistor region 3 and the memory cell array region 4 is further constructed.

The substrate 2 is configured by, for example, a silicon (Si) single-crystal substrate.

### (2) Structure of Transistor Region 3

The transistor region 3 is arranged on the substrate 2. The transistor region 3 here includes a semiconducting device such as a complementary (Complementary type) insulated-gate field-effect transistor (IGPBT: Insulated Gate Field Effect Transistor). The insulated-gate field-effect transistor includes at least both a field effect transistor (MISFET: Metal Insulator Semiconductor Field Effect Transistor) having a metal/insulator/semiconductor structure and a field effect transistor (MOSFET: Metal Oxide Semiconductor Field Effect Transistor) having a metal/oxide/semiconductor structure.

A circuit used for a system configuration of the nonvolatile memory device 1 is disposed in the transistor region 3. The circuit used for the system configuration of the nonvolatile memory device 1 is, for example, an input circuit, an output circuit, an information write circuit, an information read circuit, or the like. These circuits are constructed by combining semiconductor devices such as insulated gate field effect transistors. The semiconductor device includes a resistor, a capacitor, and the like.

### (3) Configuration of Memory Cell Array Region 4

The memory cell array region 4 includes a first wiring 41, a second wiring 42, a third wiring 43, a memory cell (memory element) 44, a first buffer layer 45, a second buffer layer 46, a third buffer layer 47, and an insulator 48.

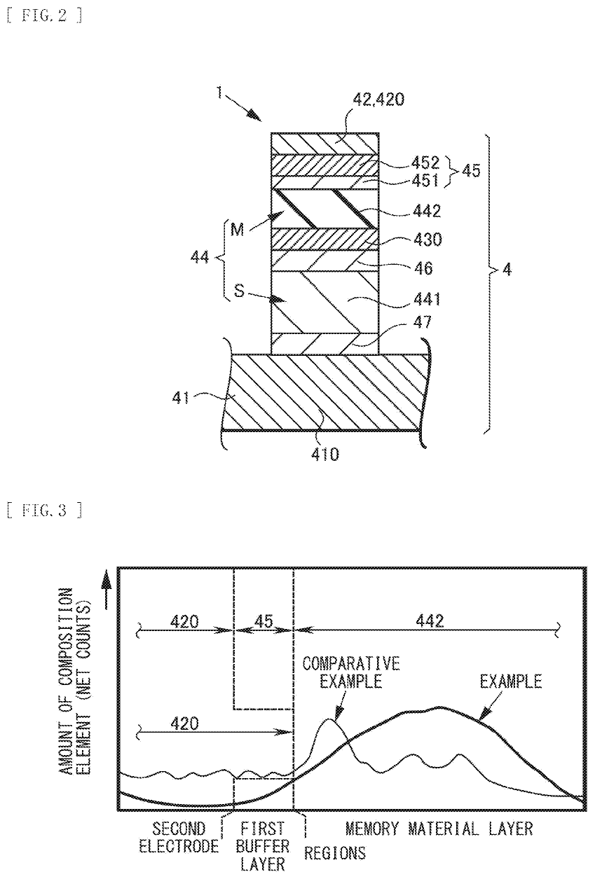

FIG. 2 is an enlarged cross-sectional view of the memory cell 44 and its vicinity.

As illustrated in FIGS. 1 and 2, the memory cell 44 is disposed at an intersection of the first wiring 41 extending in a left-right direction on the paper surface and the second wiring 42 intersecting with the first wiring 41 and extending in a front-rear direction on the paper surface, for example. The second wiring 42 is, for example, orthogonal to the first wiring 41. The first wiring 41 is used as a bit line, and the second wiring 42 is used as a word line.

The first wiring 41 includes, for example, tungsten (W) having a film thickness of not less than 30 nm and not more than 100 nm. The second wiring 42 includes, for example, tungsten having a film thickness of not less than 30 nm and not more than 100 nm.

Each of the first wiring 41 and the second wiring 42 may be configured by a wiring material containing one or more elements selected from tungsten nitride (WN), titanium nitride (TiN), copper (Cu), aluminum (Al), molybdenum (Mo), tantalum (Ta), tantalum nitride (TaN), ruthenium (Ru), and cobalt (Co). Each of the first wiring 41 and the second wiring 42 may be configured by silicide which is a compound of one or more of the above-mentioned elements and silicon (Si).

The memory cell 44 is disposed between the first electrode 410 and the second electrode 420. The first electrode 410 is a portion of the first wiring 41 that overlaps the second wiring 42 in a plan view. That is, a portion of the first wiring 41 also serves as the first electrode 410. However, in the present embodiment, the first electrode 410 may be provided separately from the first wiring 41, and the first wiring 41 and the first electrode 410 may be electrically coupled to each other. In a case where the first wiring 41 and the first electrode 410 are provided separately, a constituent material of the first wiring 41 and a constituent material of the first electrode 410 may be the same as or different from each other. The first electrode 410 is configured as a lower electrode. The second electrode 420 is a portion of the second wiring 42 that overlaps the first wiring 41 in a plan view. That is, a portion of the second wiring 42 also serves as the second electrode 420. However, in the present embodiment, the second electrode 420 may be provided separately from the second wiring 42, and the second wiring 42 and the second electrode 420 may be electrically coupled to each other. In a case where the second wiring 42 and the second electrode 420 are provided separately, a constituent material of the second wiring 42 and a constituent material of the second electrode 420 may be the same as or different from each other. In an example illustrated in FIGS. 1 and 2, the second electrode 420 is disposed above the first electrode 410 and is configured as an upper electrode.

The memory cell 44 includes a cell selection unit S and a memory unit M. The cell selection unit S and the memory unit M are electrically coupled in series between the first electrode 410 and the second electrode 420. The memory cell 44 is formed in a pillar shape between the first electrode 410 and the second electrode 420. As illustrated in FIG. 1, an insulator 48 is formed in the memory cell array region 4, including between the memory cells 44.

As illustrated in FIGS. 1 and 2, the cell selection unit S is disposed on the first electrode 410. The cell selection unit S has a two-terminal structure. That is, a lower surface side of the cell selection unit S is electrically coupled to the first wiring 41. An upper surface side of the cell selection unit S is electrically coupled to the memory unit M. In the cell selection unit S, a high resistance state is an off state (a non-selected state) and a low resistance state is an on state (a selected state). The cell selection unit S includes a selector material layer 441. The selector material layer 441 is configured by, for example, a chalcogenide material (GaTeO) having a thickness of not less than 20 nm and not more than 60 nm.

The memory unit M is disposed on the cell selection unit S with a third electrode 430 interposed therebetween. The memory unit M has a two-terminal structure in which a lower surface side is electrically coupled to the cell selection unit S and an upper surface side is electrically coupled to the second electrode 420. The memory unit M is able to hold a high resistance state or a low resistance state. The memory unit M is able to store the information “1” or the information “0” by its own resistance change.

The memory unit M includes a memory material layer 442. The memory material layer 442 includes at least a transition metal element, for example. The memory material layer 442 includes, for example, an ion-supplying layer and a memory layer (CuZrTe) having a thickness of not less than 10 nm and not more than 50 nm. In the memory material layer 442 configured by CuZrTe, Cu is a composition element that forms a filament.

The third electrode 430 is configured as an intermediate electrode disposed between the cell selection unit S and the memory unit M. The third electrode 430 is formed in a pillar shape as with the memory cell 44. The third electrode 430 includes, for example, TiN having a thickness of not less than 5 nm and not more than 25 nm.

### (4) Configuration of First Buffer Layer 45

A first buffer layer 45 is disposed in the memory cell 44. The first buffer layer 45 is provided on the memory material layer 442 of the memory unit M of the memory cell 44. That is, the first buffer layer 45 is disposed between the memory material layer 442 and the second electrode 420. In the first buffer layer 45, a segregation of a composition element of the memory material layer 442 is smaller than that of the second electrode 420. A composition element of the memory material layer 442 is, for example, Cu as a first element that generates the filament.

In the first embodiment, the first buffer layer 45 has a composite structure including a lower buffer layer 451 provided on the memory material layer 442 and an upper buffer layer 452 provided on the lower buffer layer 451. The lower buffer layer 451 includes, for example, carbon (C) having a thickness of not less than 5 nm and not more than 35 nm. The upper buffer layer 452 includes, for example, TiN having a thickness of not less than 5 nm and not more than 35 nm. In both the lower layer buffer layer 451 and the upper layer buffer layer 452, a segregation of a composition element of the memory material layer 442 is smaller than that of the second electrode 420. Moreover, the lower buffer layer 451 and the upper buffer layer 452 are electrically conductive materials having suitable electrical resistance. Therefore, the first buffer layer 45 is used as a resistor electrically coupled to each of the memory unit M and the cell selection unit S to limit a current.

The first buffer layer 45 having the small segregation of composition element and able to appropriately limit the current is set to a thickness of not less than 3 nm and not more than 50 nm in the nonvolatile memory device 1 in which, for example, a “2XnmHP” technology node (Technology node) is adopted. The technology node is an indicator of a microfabrication technology defined by the International Semiconductor Technology Roadmap (ITRS: International Technology Roadmap for Semiconductors).

The first buffer layer 45 may include nitrogen (N), Ti, or zirconium (Zr) instead of C and TiN described above.

Here, an Example of a state of segregation of a composition element where the first buffer layer 45 is provided between the memory material layer 442 and the second electrode 420 in the nonvolatile memory device 1 will be described with reference to FIG. 3. FIG. 3 illustrates a line-profile (line profile) of a composition element by energy dispersive X-ray spectroscopy (EDX: Energy Dispersive X-ray Spectroscopy). A horizontal axis represents regions of the memory material layer 442, the first buffer layer 45, and the second electrode 420 from the right side to the left side. A vertical axis represents an amount of composition element (Net counts) of the memory material layer 442, and represents, here, an amount of Cu element.

In the Example, the first buffer layer 45 is provided between the memory material layer 442 and the second electrode 420. Here, W is used for the second electrode 420, and a single layer of C having a 5 nm thickness is used for the first buffer layer 45. In this laminated structure, after performing a heat treatment at 400° C., the line profile by the energy dispersive X-ray analysis method was measured.

As illustrated in FIG. 3, the memory material layer 442 maintains a sufficient amount of Cu element to rewrite information. Further, in a thickness direction of the memory material layer 442, a fluctuation in the amount of Cu element of the memory material layer 442 is small, and the distribution of the amount of Cu element has a gentle shape. That is, the segregation of Cu element from the memory material layer 442 to the first buffer layer 45 is small, and the first buffer layer 45 blocks the segregation of Cu element. Therefore, the segregation of Cu element from the memory material layer 442 to the second electrode 420 is small.

FIG. 3 illustrates a comparative example together with the Example. In the comparative example, the second electrode 420 is formed on the memory material layer 442, and the first buffer layer 45 is not provided between the memory material layer 442 and the second electrode 420. In a structure according to the comparative example, the amount of Cu element in the memory material layer 442 is smaller than the amount of Cu element in the memory material layer 442 according to the Example. Further, in the thickness direction of the memory material layer 442, the fluctuation in the amount of Cu element in the memory material layer 442 is large, and the distribution of the amount of Cu element has a shape that repeats the undulation. The segregation of Cu element from the memory material layer 442 to the second electrode 420 is larger than that in the Example.

### (5) Configuration of Second Buffer Layer 46

Referring back to FIGS. 1 and 2, the memory cell 44 is further provided with a second buffer layer 46 in addition to the first buffer layer 45. The second buffer layer 46 is disposed on the selector material layer 441 configuring the cell selection unit S of the memory cell 44. That is, the second buffer layer 46 is disposed between the selector material layer 441 and the third electrode 430. In the second buffer layer 46, as in the first buffer layer 45, a segregation of a composition element of the memory material layer 442 is smaller than that of the second electrode 420.

In the first embodiment, the second buffer layer 46 has a single-layer structure provided on the selector material layer 441. The second buffer layer 46 includes C as a second element or a third element having a thickness of, for example, 5 nm or more and 35 nm or less.

In the first embodiment, the third electrode 430 is disposed on the second buffer layer 46. Further, the third electrode 430 includes TiN having a smaller segregation of the composition element of the memory material layer 442 than the second electrode 420. Therefore, the third electrode 430 or a portion of the second buffer layer 46 side thereof serves as a buffer layer. Therefore, similarly to the first buffer layer 45, a buffer layer having a composite structure in which the second buffer layer 46 is a lower buffer layer and the third electrode 430 or a portion thereof is an upper buffer layer is generated.

### (6) Configuration of Third Buffer Layer 47

In addition to the first buffer layer 45 and the second buffer layer 46, a third buffer layer 47 is further disposed in the memory cell 44. The third buffer layer 47 is disposed under the selector material layer 441 configuring the cell selection unit S of the memory cell 44. That is, the third buffer layer 47 is disposed between the first electrode 410 and the selector material layer 441.

The third buffer layer 47 has a single-layer structure including the same composition element as the second buffer layer 46. The third buffer layer 47 includes C as a second element having a thickness of, for example, 5 nm or more and 35 nm or less.

### (7) Configuration of Wiring Region 5

As illustrated in FIG. 1, the wiring region 5 is disposed on the memory cell array region 4. In the first embodiment, an example in which the memory cells 44 of the memory cell array region 4 have a single-layer (one-stage) structure is described, but the memory cell array region 4 may have a plurality of (multi-stage) structures in which the memory cells 44 have two or more layers. In a case where the memory cell array region 4 has a plurality of structures, the wiring region 5 is disposed on the uppermost memory cell 44.

The wiring region 5 is not limited to the number of wiring layers described above, but is configured by a two-layer wiring structure (multi-layer wiring structure) including the first wiring 51 and the second wiring 52.

The first wiring 51 is formed on the insulator 48 and extends in the same direction as the first wiring 41 of the memory cell array region 4. The second wiring 52 is disposed on the first wiring 51 with the interlayer insulating layer 53 interposed therebetween and extends in the same direction as the second wiring 42 of the memory cell array region 4.

The first wiring 51 and the second wiring 52 are provided in an interlayer insulating layer 53, for example, and are electrically coupled to each other through a connection layer 55 indicated by a broken line.

A protective film 54 is formed effectively over the entire area of the wiring region 5 including the second wiring 52.

[Method of Manufacturing Nonvolatile Memory Device 1]

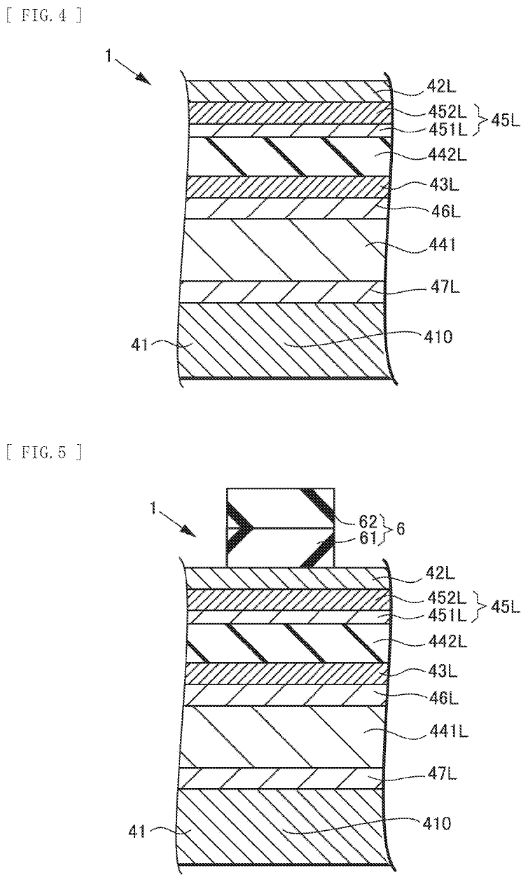

A method of manufacturing the nonvolatile memory device 1 according to the first embodiment includes the following manufacturing steps illustrated in FIGS. 4 to 6. Hereinafter, a method of manufacturing the memory cell array region 4 will be described in detail.

First, the first wiring 41 and the first electrode 410 are formed on the substrate 2 (see FIG. 4). As illustrated in FIG. 4, the third buffer layer 47L, the selector material layer 441L, the second buffer layer 46L, the third wiring layer 43L, the memory material layer 442L, the first buffer layer 45L, and the second wiring layer 42L are sequentially formed on the first wiring 41 and the first electrode 410. Here, when forming the first buffer layer 45L, the lower buffer layer 451L and the upper buffer layer 452L are sequentially formed.

As illustrated in FIG. 5, a mask 6 is formed on the second wiring layer 42L. The mask 6 is formed as an etching hard mask. The mask 6 is formed by, for example, a laminated film of a silicon nitride (SiN) film having a thickness of 50 nm or more and 100 nm or less and a silicon oxide (SiO) film laminated on the SiN film and having a thickness of 40 nm or more and 80 nm or less.

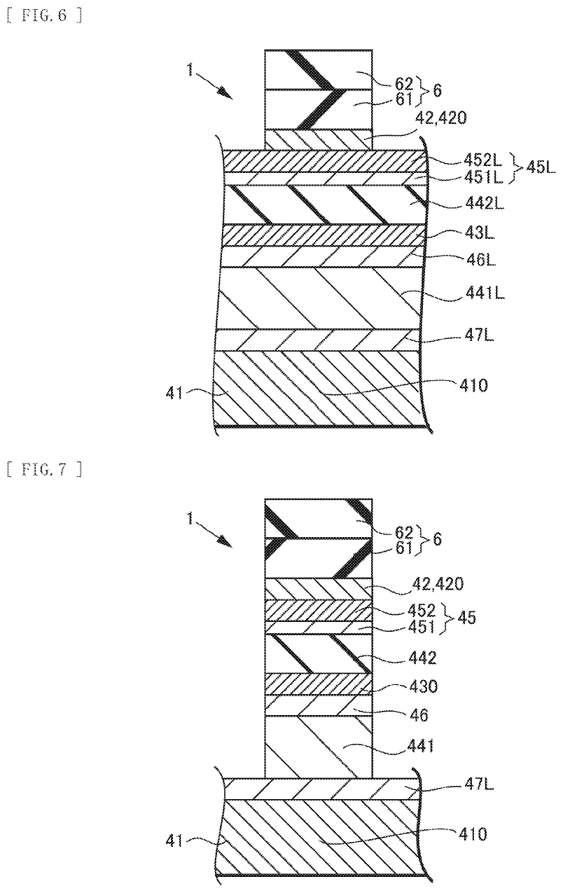

By patterning the second wiring layer 42L using the mask 6, the second wiring 42 and the second electrode 420 are formed from the second wiring layer 42L as illustrated in FIG. 6. For patterning the second wiring layer 42L, dry etching using, for example, a halogen-based gas is performed as a first etching process.

Here, in the first embodiment, the second wiring layer 42L is configured by W, for example, and the upper buffer layer 452L of the first buffer layer 45L is configured by TiN, for example. Therefore, the second wiring layer 42L and the upper buffer layer 452L each have an etching selectivity with respect to the first etching, and thus the first buffer layer 45L is also used as an etching stopper.

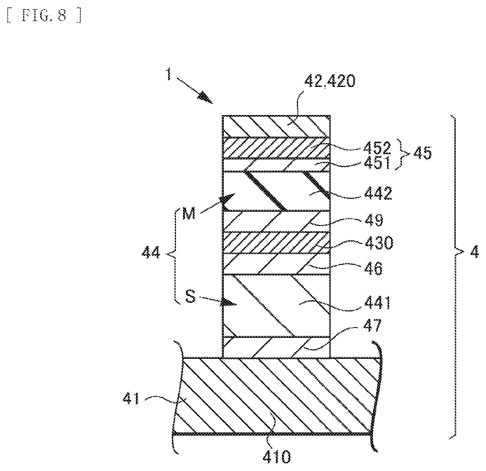

Subsequently, the first buffer layer 45L, the memory material layer 442L, the third wiring layer 43L, the second buffer layer 46L, and the selector material layer 441L are sequentially patterned using the mask 6. As illustrated in FIG. 7, the first buffer layer 45, the memory material layer 442, the third wiring 43, the third electrode 430, the second buffer layer 46, and the selector material layer 441 are sequentially formed by the patterning. The first buffer layer 45 is formed from the first buffer layer 45L. The memory material layer 442 is formed from the memory material layer 442L. The third wiring 43 and the third electrode 430 are formed from the third wiring layer 43L. The second buffer layer 46 is formed from the second buffer layer 46L. The selector material layer 441 is formed from the selector material layer 441L.

When the memory material layer 442 is formed, the memory unit M is formed. In addition, when the selector material layer 441 is formed, the cell selection unit S is formed.

For the patterning here, halogen-free dry etching is used as a second etching. Because the third wiring 43 and the third electrode 430 include TiN in the first embodiment, a W layer is not present from the first buffer layer 45 to the third buffer layer 47L to provide a W-less configuration. Thus, it is possible to perform the patterning continuously from the first buffer layer 45L to the selector material layer 441L by using the second etching.

Further, because the memory material layer is halogen-free, a damage caused by halogen does not occur in the memory material layer 442, that is, in the memory unit M.

Thereafter, the third buffer layer 47L is patterned using the mask 6 to obtain the third buffer layer 47 from the third buffer layer 47L (see FIG. 2). The third buffer layer 47 is used as an etching stopper during patterning from the first buffer layer 45L to the selector material layer 441L.

Thereafter, as illustrated in FIG. 2, the insulator 48 and the wiring region 5 are sequentially formed, whereby the method of manufacturing the nonvolatile memory device 1 according to the first embodiment is completed.

(Workings and Effects)

In the nonvolatile memory device 1 according to the first embodiment, as illustrated in FIGS. 1 and 2, the first buffer layer 45 is provided between the memory material layer 442 of the memory unit M of the memory cell 44 and the second electrode 420. As illustrated in FIG. 3, in the first buffer layer 45, it is possible to make the segregation of the composition element of the memory material layer 442 smaller than that of the second electrode 420. The composition element is Cu as the first element. That is, the fluctuation in the composition element in the memory material layer 442 is reduced. Therefore, a fluctuation in electrical characteristics and variations in the electrical characteristics of the memory material layer 442 are reduced. Therefore, it is possible to achieve high performance in the nonvolatile memory device 1.

In addition, the first buffer layer 45 is used as a resistor coupled to the memory cell 44. That is, the memory cell 44 has a current limiting function. Therefore, it is possible to obtain optimal device characteristics by appropriately adjusting a film thickness of the first buffer layer 45, and to achieve high performance in the nonvolatile memory device 1.

In the nonvolatile memory device 1, as illustrated in FIGS. 1 and 2, the second buffer layer 46 is formed between the selector material layer 441 of the cell selection unit S of the memory cell 44 and the third electrode 430. In the second buffer layer 46, as in the first buffer layer 45, it is possible to make the segregation of the composition element of the memory material layer 442 smaller than that of the second electrode 420. Therefore, the fluctuation in the electrical characteristics and the variations in the electrical characteristics of the memory material layer 442 are reduced. Therefore, it is possible to achieve the high performance in the nonvolatile memory device 1.

In addition, because the second buffer layer 46 is used as a resistor coupled to the memory cell 44, the memory cell 44 has a current limiting function as with the first buffer layer 45, and it is possible to achieve the high performance in the nonvolatile memory device 1.

In the nonvolatile memory device 1, as illustrated in FIGS. 1 and 2, the third buffer layer 47 is formed between the first electrode 410 and the selector layer. The third buffer layer 47 includes the composition element as the second element identical to the composition element of the second buffer layer 46. Although the manufacturing method of the nonvolatile memory device 1 is illustrated in FIGS. 4 to 7, the third buffer layer 47 is used as the etching stopper.

Therefore, it is possible to perform the patterning of each layer continuously from the first buffer layer 45 to the third buffer layer 47 by using halogen-free dry etching (the second etching) to form the memory cell 44. In the formation of the memory cell 44, a damage caused by the dry etching using a halogen-based gas does not occur in the memory material layer 442. Therefore, the fluctuation in the electrical characteristics and the variations in the electrical characteristics of the memory material layer 442 are reduced, making it possible to achieve the high performance in the nonvolatile memory device 1.

In the nonvolatile memory device 1, as illustrated in FIGS. 1 and 2, the memory material layer 442 configures the memory unit M that stores information by resistance change. The selector material layer 441 configures the cell selection unit S. The memory unit M and the cell selection unit S construct the memory cell 44 of the resistance change memory.

Therefore, it is possible to achieve high performance in the nonvolatile memory device 1 constructed by the resistance change memory.

In the nonvolatile memory device 1 illustrated in FIGS. 1 and 2, the memory material layer 442 includes a transition metal element. The memory material layer 442 configures the memory unit M and configures the memory cell 44. Therefore, it is possible to achieve high performance in the nonvolatile memory device 1.

In the nonvolatile memory device 1 illustrated in FIGS. 1 and 2, the composition element of the memory material layer 442 is Cu that generates the filament. The memory material layer 442 including the composition element configures the memory unit M, and configures the memory cell 44. Therefore, it is possible to achieve high performance in the nonvolatile memory device 1.

In the nonvolatile memory device 1, the second electrode 420 illustrated in FIGS. 1 and 2 includes one or more elements selected from W, WN, TiN, Cu, Al, Mo, Ta, TaN, Ru, and Co. Because the electrode material containing this element has high reliability as an electrode material and an existing semiconductor manufacturing process is usable, it is possible to achieve high performance easily in the nonvolatile memory device 1.

In the nonvolatile memory device 1, the first buffer layer 45 illustrated in FIGS. 1 and 2 includes one or more elements selected from C, N, Ti, TiN, and Zr. In the first buffer layer 45, the segregation of the composition element of the memory material layer 442, such as Cu, is smaller than that of the second electrode 420, and a series resistor suitable for the memory cell 44 is generatable. Therefore, it is possible to achieve high performance in the nonvolatile memory device 1. It is possible to obtain similar workings and effects for the second buffer layer 46 and the third buffer layer 47 as well.

In the nonvolatile memory device 1, the first buffer layer 45, the second buffer layer 46, and the third buffer layer 47 illustrated in FIGS. 1 and 2 each include the C layer. In the C layer of the first buffer layer 45 and the second buffer layer 46, the segregation of the composition element of the memory material layer 442, here Cu, is smaller than that of the second electrode 420, and it is possible for the memory cell 44 to be provided with the current limiting function. On the other hand, the C layer of the third buffer layer 47 is used as the etching stopper in the manufacturing method of the nonvolatile memory device 1 illustrated in FIGS. 4 to 7. Therefore, it is possible to achieve high performance in the nonvolatile memory device 1.

In the nonvolatile memory device 1, as illustrated in FIGS. 1 and 2, the memory unit M and the cell selection unit S are electrically coupled directly between the first electrode 410 and the second electrode 420. The memory cell 44 is a resistance change memory cell. The memory cell 44 constructs a cross-point memory disposed at an intersection of the first wiring 41 coupled to the first electrode 410 and the second wiring 42 crossing the first wiring 41 and coupled to the second electrode 420. Therefore, in the nonvolatile memory device 1, it is possible to achieve high integration while achieving high performance.

In the method of manufacturing the nonvolatile memory device 1, as illustrated in FIG. 4, the first electrode 410, the memory material layer 442L, the first buffer layer 45L, and the second wiring layer 42L are formed on the substrate 2. The memory material layer 442L is formed on the first electrode 410. The first buffer layer 45L is formed on the memory material layer 442L. In the first buffer layer 45L, the segregation of the composition element in the memory material layer 442L is smaller than that in the second wiring layer 42L. In addition, the first buffer layer 45L serves as the stopper for the etching of the second wiring layer 42L.

Next, as illustrated in FIG. 6, the patterning is performed on the second wiring layer 42L by using the first etching, and the second electrode 420 is formed from the second wiring layer 42L. Subsequently, as illustrated in FIG. 7, the patterning is performed on the first buffer layer 45L and the memory material layer 442L using the second etching that is different from the first etching. By this patterning, the first buffer layer 45 is formed from the first buffer layer 45L, and the memory material layer 442 is formed from the memory material layer 442L.

Therefore, because the first buffer layer 45L covers the memory material layer 442L as the stopper during the first etching, it is possible to eliminate a damage to the memory material layer 442L caused by the first etching. For example, for the first etching, the dry etching using a halogen-based gas optimal for microfabrication is used, and for the second etching, halogen-free dry etching is usable. Therefore, because the memory material layer 442 is not eventually damaged, it is possible to provide a method of manufacturing the nonvolatile memory device 1 that makes it possible to achieve high performance.

### Second Embodiment

### [Configuration of Nonvolatile Memory Device 1]

As illustrated in FIG. 8, the nonvolatile memory device 1 according to the second embodiment of the present disclosure further includes a fourth buffer layer 49 in the memory cell 44 of the nonvolatile memory device 1 according to the first embodiment. The fourth buffer layer 49 is disposed on the third electrode 430 and is formed between the third electrode 430 and the memory material layer 442 of the memory unit M.

The fourth buffer layer 49 includes a composition element, as a third element, that is the same as the composition element of the second buffer layer 46. Specifically, the fourth buffer layer 49 is formed by a single layer of C having a thickness of, for example, 5 nm or more and 35 nm or less.

When the fourth buffer layer 49 is formed, the memory cell 44 has a structure in which upper and lower portions of the memory material layer 442 are sandwiched between the first buffer layer 45 and the fourth buffer layer 49, and upper and lower portions of the selector material layer 441 are sandwiched between the second buffer layer 46 and the third buffer layer 47.

A configuration other than the fourth buffer layer 49 is the same as the configuration of the nonvolatile memory device 1 according to the first embodiment.

(Workings and Effects)

In the nonvolatile memory device 1 according to the second embodiment, as illustrated in FIG. 8, the fourth buffer layer 49 is formed between the memory material layer 442 of the memory unit M of the memory cell 44 and the third electrode 430. In the fourth buffer layer 49, as in the first buffer layer 45 illustrated in FIG. 3, the segregation of the composition element of the memory material layer 442 is smaller than that of the second electrode 420. That is, the fluctuation in the composition element in the memory material layer 442 is reduced. Therefore, the fluctuation in the electrical characteristics and the variations in the electrical characteristics of the memory material layer 442 are reduced. Therefore, it is possible to achieve high performance in the nonvolatile memory device 1.

In the nonvolatile memory device 1 according to the second embodiment, it is possible to omit the second buffer layer 46.

### Other Embodiments

The present technology is not limited to the above-described embodiments, and various modifications can be made without departing from the gist thereof.

For example, in the nonvolatile memory device, in a case where the memory material layer of the memory cell employs a filament switching structure having a two-layer structure of, for example, an ion layer and a switching layer, it is possible to achieve the following structure. That is, a structure from the first electrode to the third electrode with the cell selection unit interposed therebetween is configured in a pillar shape, and a structure from the storage unit to the second electrode is configured in the same shape as the second electrode and the second wiring in a plan view.

In addition, the present technology is not limited to the cross-point memory. Further, the present technology is not limited to a resistance change memory, and is widely applicable to a ferroelectric memory or the like.

In the present disclosure, the first buffer layer is provided between the memory material layer including the first element and the second electrode. The segregation of the first element in the first buffer layer is smaller than the segregation of the first element in the second electrode. That is, the fluctuation in the first element in the memory material layer is small. Therefore, the fluctuation in the electrical characteristics and the variations in the electrical characteristics of the memory material layer are reduced. Therefore, it is possible to provide a nonvolatile memory device and a method of manufacturing the same that make it possible to achieve high performance.

<Configuration of Present Technology>

The present technology has the following configurations.

(1)

A nonvolatile memory device including:
a first electrode;
a memory material layer provided on the first electrode and including a first element;
a second electrode provided on the memory material layer; and
a first buffer layer provided between the memory material layer and the second electrode, the first buffer layer having a segregation of the first element smaller than a segregation of the first element in the second electrode.
   (2)

The nonvolatile memory device according to (1), further including:
a third electrode provided between the first electrode and the memory material layer;
a selector material layer provided between the first electrode and the third electrode; and
a second buffer layer provided between the selector material layer and the third electrode, the second buffer layer having a segregation of the first element smaller than the segregation of the first element in the second electrode.
   (3)

The nonvolatile memory device according to (2), further including a third buffer layer formed between the first electrode and the selector material layer, in which
the second buffer layer and the third buffer layer include a second element.
   (4)

The nonvolatile memory device according to (2) or (3), further including a fourth buffer layer provided between the memory material layer and the third electrode, in which
the second buffer layer and the fourth buffer layer include a third element.
   (5)

The nonvolatile memory device according to any one of (2) to (4), in which
the memory material layer configures a memory unit that stores information by a resistance change,
the selector material layer configures a cell selection unit, and
the memory unit and the cell selection unit configure a resistance change memory cell.
   (6)

The nonvolatile memory device according to any one of (1) to (5), in which the memory material layer includes a transition metal element.

(7)

The nonvolatile memory device according to any one of (1) to (6), in which the first element of the memory material layer is copper that generates a filament.

(8)

The nonvolatile memory device according to any one of (1) to (7), in which the second electrode includes at least one element selected from tungsten, titanium tungsten, titanium nitride, copper, aluminum, molybdenum, tantalum, tantalum nitride, ruthenium, and cobalt.

(9)

The nonvolatile memory device according to any one of (1) to (8), in which the first buffer layer includes one or more elements selected from carbon, nitrogen, titanium, titanium nitride, and zirconium.

(10)

The nonvolatile memory device according to (3) or (4), in which the first buffer layer, the second buffer layer, and the third buffer layer include a carbon layer.

(11)

The nonvolatile memory device according to (5), in which
the memory unit and the cell selection unit are electrically coupled between the first electrode and the second electrode directly, and
the resistance change memory cell is disposed at an intersection of a first wiring coupled to the first electrode and a second wiring that crosses the first wiring and is coupled to the second electrode.
   (12)

A method of manufacturing a nonvolatile memory device including:
forming a first electrode on a substrate;
forming a memory material layer including a first element on the first electrode; forming a first buffer layer on the memory material layer;
forming, on the first buffer layer, a second electrode layer having a segregation of the first element larger than a segregation of the first element in the first buffer layer;
forming a second electrode by patterning the second electrode layer by a first etching process that uses the first buffer layer as a stopper; and
patterning the first buffer layer and the memory material layer by a second etching process that is different from the first etching process.

The present application claims the benefit of Japanese Priority Patent Application JP2021-009054 filed with the Japan Patent Office on Jan. 22, 2021, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A nonvolatile memory device comprising:
a first electrode;
a memory material layer provided on the first electrode and including a first element;
a second electrode provided on the memory material layer; and
a first buffer layer provided between the memory material layer and the second electrode, the first buffer layer having a segregation of the first element smaller than a segregation of the first element in the second electrode.

2. The nonvolatile memory device according to claim 1, further comprising:
a third electrode provided between the first electrode and the memory material layer;
a selector material layer provided between the first electrode and the third electrode; and
a second buffer layer provided between the selector material layer and the third electrode, the second buffer layer having a segregation of the first element smaller than the segregation of the first element in the second electrode.

3. The nonvolatile memory device according to claim 2, further comprising a third buffer layer formed between the first electrode and the selector material layer, wherein
the second buffer layer and the third buffer layer include a second element.

4. The nonvolatile memory device according to claim 2, further comprising a fourth buffer layer provided between the memory material layer and the third electrode, wherein
the second buffer layer and the fourth buffer layer include a third element.

5. The nonvolatile memory device according to claim 2, wherein
the memory material layer configures a memory unit that stores information by a resistance change,
the selector material layer configures a cell selection unit, and
the memory unit and the cell selection unit configure a resistance change memory cell.

6. The nonvolatile memory device according to claim 5, wherein the memory material layer includes a transition metal element.

7. The nonvolatile memory device according to claim 1, wherein the first element of the memory material layer is copper that generates a filament.

8. The nonvolatile memory device according to claim 1, wherein the second electrode includes at least one element selected from tungsten, titanium tungsten, titanium nitride, copper, aluminum, molybdenum, tantalum, tantalum nitride, ruthenium, and cobalt.

9. The nonvolatile memory device according to claim 8, wherein the first buffer layer includes one or more elements selected from carbon, nitrogen, titanium, titanium nitride, and zirconium.

10. The nonvolatile memory device according to claim 3, wherein the first buffer layer, the second buffer layer, and the third buffer layer include a carbon layer.

11. The nonvolatile memory device according to claim 5, wherein
the memory unit and the cell selection unit are electrically coupled between the first electrode and the second electrode directly, and
the resistance change memory cell is disposed at an intersection of a first wiring coupled to the first electrode and a second wiring that crosses the first wiring and is coupled to the second electrode.

12. A method of manufacturing a nonvolatile memory device, the method comprising:
forming a first electrode on a substrate;
forming a memory material layer including a first element on the first electrode;
forming a first buffer layer on the memory material layer;
forming, on the first buffer layer, a second electrode layer having a segregation of the first element larger than a segregation of the first element in the first buffer layer;
forming a second electrode by patterning the second electrode layer by a first etching process that uses the first buffer layer as a stopper; and
patterning the first buffer layer and the memory material layer by a second etching process that is different from the first etching process.
